(19) United States
(12) Patent Application Publication
(10) Pub. No.: US 2026/0332965 A1
(43) Pub. Date: Oct. 22, 2026

(54) MICROMECHANICAL STRUCTURE AND MICROMECHANICAL SPEAKER

(71) Applicant: Robert Bosch GmbH, Stuttgart (DE)

(72) Inventor: Stefan Pinter, Reutlingen (DE)

(21) Appl. No.: 19/122,487

(22) PCT Filed: Oct. 2, 2023
(86) PCT No.: PCT/EP2023/077254

§ 371 Date: Apr. 18, 2025

(30) Foreign Application Priority Data
Oct. 25, 2022 (DE) 10 2022 211 284.9

(51) Int. Cl. H04R 19/02; B81B 3/00; H04R 3/00; H04R 9/06; H04R 17/00; H04R 23/00

(52) U.S. Cl. CPC H04R 19/02; B81B 3/007; H04R 3/00; B81B 2201/0257; B81B 2203/0127; B81B 2203/0163; B81B 2203/04; H04R 9/06; H04R 17/00; H04R 23/002; H04R 2201/003; H04R 2440/01

(57) ABSTRACT

A micromechanical structure and a micromechanical speaker. The micromechanical structure includes at least one movable bending unit including a plurality of bending elements designed as deflectable spring elements. A first spring element includes a linear spring constant and a second spring element includes a non-linear spring constant in an associated force-displacement diagram. The first and/or second spring element can be functionally actuated, in the configuration of the micromechanical structure as a speaker, to generate sound. The first and second spring elements are mechanically coupled such that their common spring characteristic curve includes an inflection point in the force-displacement diagram. The first and/or second spring element are laterally and/or rotationally pre-deflected using at least one actuating element to set the common spring characteristic curve for functional operation of the micromechanical structure. The at least one actuating element effects a temporary or permanent pre-deflection.

### FIELD

The present invention relates to a micromechanical structure and a micromechanical speaker.

### BACKGROUND INFORMATION

A micromechanical structure (designed as an acceleration sensor) with a plurality of bending elements is described in China Patent Application No. CN 109085382A.

### SUMMARY

An object of the present invention is to provide an improved micromechanical structure and an optimized micromechanical speaker.

This object is may be achieved by certain features of the present invention. Advantageous example embodiments of the present invention are disclosed herein.

The present invention provides a micromechanical structure and a micromechanical speaker. According to an example embodiment of the present invention, the micromechanical structure comprises at least one movable bending unit that comprises a plurality of bending elements, wherein the plurality of bending elements are designed as deflectable spring elements. At least one first spring element comprises a linear spring constant in an associated force-displacement diagram, and/or at least one second spring element comprises a non-linear spring constant in an associated force-displacement diagram. The first spring element and/or the second spring element are functionally actuatable, in particular functionally actuatable to generate sound, in order to form a micromechanical speaker. The first spring element and/or the second spring element are mechanically coupled, such that their common spring characteristic curve comprises an inflection point in the force-displacement diagram. The first spring element and/or the second spring element are laterally and/or rotationally pre-deflected by means of at least one actuating element in order to set the common spring characteristic curve for a functional operation of the micromechanical structure, wherein the at least one actuating element effects a temporary or permanent pre-deflection. When the micromechanical structure is designed as a micromechanical speaker, the first spring element and/or the second spring element are designed to be functionally actuatable to generate sound. The micromechanical speaker further comprises a signal processing unit for applying and processing signals from the micromechanical structure. The signal processing unit can also form or comprise a control unit for controlling the micromechanical structure.

Advantageously, the spring stiffness is reduced by the pre-deflection to values that are required for the function or functional operation of the micromechanical structure. The spring stiffness for lateral, vertical and rotational deflection can advantageously be configured to vary, thus offering the greatest possible flexibility in implementation. For example, the spring stiffness can be configured to be small for lateral deflections (after pre-deflection) and large for vertical deflections. In a similar way, unwanted (possibly higher) vibration modes can also be reduced or avoided.

The setting of the common spring characteristic curve for a functional operation of the micromechanical structure can mean a further deflection of the first spring element and/or the second spring element in an approximately linear range about the inflection point of the common spring characteristic curve in the force-displacement diagram. In this case, the functional operation of the micromechanical structure, the functional actuation or the further deflection of the first and/or second spring element can in each case be understood as synonyms. The further deflection of the first and/or second spring element or of an element attached to or connected to the spring elements mentioned, which is not designed as a spring element, leads to a movement of the first and/or second spring element, as a result of which the adjacent air is also set in motion.

The acoustic performance of a MEMS speaker is created by the compression of the air by a moving membrane, lamella or by moving spring elements (e.g., a first and/or second spring element), as described above. The larger the volume of the compressed air, i.e. the surface area or the amplitude of movement of the membrane (with vertical deflection) or spring element or lamella (with lateral deflection) with the frequencies corresponding to the desired sounds, the greater the acoustic performance of the speaker.

The sound pressure level is a measure of the sound power, which is proportional to the square of the sound pressure. In the case of MEMS speakers, the achievable deflection is limited by the limited force of the elements. The deflection of the membrane, the spring element(s) or the lamella is generally proportional to the force over a wide range. The proportionality constant is the “spring constant” or “stiffness” of the membrane, spring element(s) or lamella. The stiffness is a function of, among other things, the membrane, spring element or lamella geometry (in the broader sense thickness/height, diameter/length) and the elastic modulus of the material. The stiffness of the membrane/spring elements/lamellae determines their resonance frequency. The resonance frequency of speakers is above the frequencies that they generate as sound during operation.

A fundamental difficulty of related art micromechanical (MEMS) speakers is that their acoustic power is insufficient for many applications. MEMS speaker with laterally deflectable lamellae is a concept for MEMS speakers with the potential to achieve high acoustic performance. In order to achieve this goal, large deflections or lamella surfaces are required. If small lateral dimensions are desired for the component, large lamella surfaces can be achieved by a large lamella height (thick functional layer). However, with a large lamella height, their stiffness also increases at the same time, which in turn reduces the deflection amplitude. In order to achieve the lowest possible spring stiffness for the greatest possible deflection with limited force, the lamellae must be very thin across their entire height. Therefore, for their structuring, very high aspect ratios (trench depth to trench width) that have so far not been reliably manufacturable and trench wall angles that are as vertical as possible with very small geometric tolerances must be realized.

With the aid of the micromechanical structure according to the present invention described above, large (high) silicon lamella surfaces or large (high) silicon spring elements can be advantageously realized with simultaneously low spring stiffness. By appropriately dimensioning the bending elements (connection of curved and/or folded elements or spring elements), the spring characteristic curve (characteristic curve) can be varied in the vicinity of this region. In this way, the spring characteristic curve can be designed to be almost linear and with a small gradient in a wide range about the inflection point. Usually, sensors and actuators are configured to operate in a linear stiffness range. If a MEMS speaker of this type—i.e., with laterally arranged bending elements (spring elements)—is brought into this range by a pre-deflection and operated, the force required for actuation is advantageously low, or large movement amplitudes—correspondingly high sound power levels—can be achieved with small forces. In particular, lamellae (laterally flexible beams) or spring elements with such a spring characteristic curve profile can be provided for silicon MEMS sensors and actuators, which can only be realized by a positive or negative spring stiffness reduced by pre-deflection.

In a further example embodiment of the present invention, the micromechanical structure is designed to be functionally actuatable for use as one of the following components: a gravimeter, a scale, in particular a nano-scale, an xy and/or rotary actuator, in particular for a translational or rotational micro-positioning element, an energy harvester, a relay that is designed to be monostable or bistable. The principle described above advantageously makes possible the realization of a wide range of applications for MEMS sensors and actuators (in silicon), also for the other applications mentioned by way of example, which are advantageously very robust against destruction by overload, and yet, due to their low stiffness during operation, make possible large movement amplitudes for sensing or actuation.

During manufacture, the component is in the characteristic curve range with a high degree of stiffness (large gradient in the spring characteristic curve in FIG. 14D) without the action of forces. This means great robustness against destruction by overload. As far as possible at the end of the manufacturing process or in order to set the function for the application situation, the movable element/the movable bending unit is temporarily or permanently deflected to such an extent that the flat characteristic curve range is reached. This means that advantageously only a small force is required for further deflection of a sensor or actuator in this range.

In a further example embodiment of the present invention, the at least one actuating element is designed to be electrostatically actuatable and/or pneumatically actuatable and/or piezoelectrically actuatable and/or magnetically actuatable and/or thermally actuatable.

Depending on the geometry of the spring elements and the actuator elements used, their spring constant or their resonance frequency can be varied via the pre-deflection, such that advantageously only a small force is required for further deflection (functional operation) of a sensor or actuator.

Conventional solutions, such as MEMS actuators/sensors designed as gravimeters, use a deflection of the seismic mass and thus of the spring elements via the Earth's gravitational field instead of an actuating element. However, pre-deflection of the lamellae of a laterally actuated MEMS speaker in the gravitational field is not possible due to the required stiffness. The function of a MEMS speaker should also not be influenced by its orientation in the gravitational field. The use of a proposed actuating element for pre-deflection of the micromechanical structure can advantageously overcome these disadvantages.

In a further example embodiment of the present invention, a first end and/or a second end of the first spring element is fixed. A first end and/or a second end of the second spring element is also fixed. A central portion of the first spring element and/or a central portion of the second spring element are mechanically coupled to one another. An electrode pair is arranged above the first spring element and/or below the first spring element and/or between the first and second spring elements as an electrostatically actuatable actuating element, which is connected to the first spring element and/or to the second spring element. When an electrical voltage is applied to the electrode pair, an electrical force is generated, which acts attractively on the electrode pair and deflects the electrode pair from a rest position, in order to effect a lateral and/or rotational pre-deflection of the first spring element and/or the second spring element.

Depending on the geometry of the spring elements and the design of the actuator elements used, their spring constant or their resonance frequency can be varied via the pre-deflection, such that only a small force is advantageously required for further deflection (functional operation) of a sensor or actuator. Instead of very narrow spring elements for a low degree of stiffness, wider, stiffer spring elements can be manufactured or used. Due to the pre-deflection, the spring stiffness is advantageously reduced to values that are required for the function. With the same absolute width tolerances in manufacturing, the absolute tolerance for stiffness is lower for wide spring elements. A narrow tolerance in the spring stiffness is a significant advantage for maintaining functional properties (e.g., small scatter in the resonance frequency of the MEMS speakers).

If the electrode pair is arranged acting in opposite directions, the functional actuation of the micromechanical structure can advantageously be carried out bidirectionally. Advantageously, the pre-deflection can thus be flexibly applied to the individual MEMS sensor or actuator requirements.

In a further example embodiment of the present invention, the electrode pair is designed to mutually engage. A first electrode of the electrode pair comprises a plurality of projections on a first side facing a second electrode of the electrode pair. The second electrode of the electrode pair comprises, on a first side facing the first electrode of the electrode pair, a plurality of projections that are arranged offset from the plurality of projections on the first side of the first electrode. The plurality of projections of the first electrode and the plurality of projections of the second electrode are designed to be tooth-like, edge-like or truncated cone-like.

Advantageously, the different geometric arrangement of the electrodes can make possible the unidirectional or bidirectional functional actuation of the proposed structure. If the electrodes of the electrode pair are designed in the shape of a truncated cone, they advantageously comprise a self-limiting effect, i.e. they cannot be moved towards one another until they stop/stick together, in contrast to the other designs of the electrodes.

In a further embodiment of the present invention, functional actuation is carried out by means of an electrostatically actuatable and/or piezoelectrically actuatable and/or magnetically actuatable actuating element, wherein a signal can be modulated onto the micromechanical structure for this purpose.

In a further example embodiment of the present invention, the functional actuation can be set unidirectionally or bidirectionally. This embodiment offers the greatest possible flexibility in implementation.

In a further example embodiment of the present invention, a laterally at least partially curved or folded tube spring can be used as the pneumatically actuatable actuating element, which is designed as a first spring element and/or as a second spring element or is attached to the first spring element and/or to the second spring element or is connected to the first spring element and/or to the second spring element. A pressure difference is created between an inner volume of the tube spring and an outer volume of the tube spring, which leads to a movement of the tube spring, in order to effect a lateral and/or rotational pre-deflection of the first spring element and/or of the second spring element. For example, various (non-exhaustive) geometric designs for the tube spring are possible: spiral, S-shaped, folded, with rounded edges, etc.

Conventional technology can thus be used advantageously for the permanent pre-deflection of the proposed structure. Since the permanent deflection is usually already carried out during the manufacturing process of the structure and the pneumatic actuation is too slow for functional actuation, the proposed type of actuation is advantageously suitable for providing a permanent pre-deflection.

In a further example embodiment of the present invention, a piezoelectric strip pair can be used as the piezoelectrically actuatable actuating element, which is attached to the first spring element and/or to the second spring element, i.e. is applied to a surface of the first spring element and/or to a surface of the second spring element or is connected to the first spring element and/or to the second spring element. When an electrical voltage of opposite polarity is applied to the piezoelectric strip pair, the piezoelectric strip pair is configured to perform an extension movement and/or compression movement, in order to effect a lateral and/or rotational pre-deflection of the first spring element and/or the second spring element.

This advantageously allows conventional technology to be implemented easily and reliably. If the micromechanical structure is designed, e.g., as an inertial sensor/acceleration sensor, the so-called “sticking” behavior of the inertial sensor can be avoided/reduced by using a spring element with a degressive-horizontal-progressive characteristic curve (e.g., FIG. 14D) and utilizing the proposed structure (including pre-deflection). The drop resistance of MEMS elements can also be advantageously increased by degressive-horizontal-progressive spring properties, such that deflection as far as the mechanical stop is only carried out at a much higher mechanical overload.

In a further example embodiment of the present invention, a busbar made of electrically conductive material in a magnetic field can be used as the magnetically actuatable actuating element. The busbar is attached to the first spring element and/or to the second spring element, i.e. applied to a surface of the first and/or second spring element or embedded in the first and/or second spring element, provided that the first and/or second spring element are in each case made of silicon, or connected to the first spring element and/or to the second spring element. When an electrical voltage is applied to the busbar, a current flow is generated, which generates a magnetic force on the busbar in the magnetic field and effects a lateral and/or rotational pre-deflection of the first spring element and/or the second spring element.

In a further example embodiment of the present invention, a bimetallic strip can be used as the thermally actuatable actuating element. The bimetallic strip is attached to the first spring element and/or to the second spring element or is connected to the first spring element and/or to the second spring element. A first end of the bimetallic strip is designed to be fixable and/or a second end of the bimetal strip is designed to be movable. When heated, the bimetallic strip is configured to perform a movement, in order to effect a lateral and/or rotational pre-deflection of the first spring element and/or the second spring element. Heating of the bimetallic strip can be achieved either by short-circuiting the bimetallic strip or by using a heating element.

In a further example embodiment of the present invention, a shape memory alloy can be used as the thermally actuatable actuating element. The shape memory alloy is attached to the first spring element and/or to the second spring element or connected to the first spring element and/or to the second spring element. A first end of the shape memory alloy is designed to be fixable and/or a second end of the shape memory alloy is designed to be movable. The shape memory alloy is configured to undergo a phase transition upon heating, wherein the phase transition brings about a structural change of the shape memory alloy, in order to effect a lateral and/or rotational pre-deflection of the first spring element and/or the second spring element.

In a further example embodiment, the movable bending unit is designed as a rotation unit with a rotation body for a rotational pre-deflection. This design can be advantageously used for sensors and actuators with rotating elements. In this way, rotary movements or actuators or sensors with rotary elements can advantageously be implemented.

In a further example embodiment of the present invention, the rotating body is designed to be substantially circular and movable. The first spring element is arranged within the rotation body, which is connected on one side to the rotation body and fixed on one side. The first spring element is designed as a pneumatically actuatable, at least partially curved or folded tube spring for the rotational pre-deflection of the first spring element and/or of at least one second spring element. For example, the at least partially curved or folded tube spring is designed as a spiral-shaped tube spring. Alternatively, other (non-exhaustive) geometric configurations are also possible, such as S-shaped, folded, with rounded edges, etc. The at least one second spring element is connected on one side to the rotation body and on one side to the fixing element, wherein the fixing element is designed to be immovable. In this way, rotary movements or actuators or sensors with rotary elements can advantageously be implemented.

In a further example embodiment of the present invention, furthermore an electrode pair is arranged between the rotation body and the fixing element as an electrostatically actuatable actuating element for the rotational pre-deflection of the first spring element and/or the at least one second spring element.

In a further example embodiment of the present invention, the first spring element and/or the at least one second spring element are arranged at least partially overlapping one another. In this case, at least partially overlapping one another can be understood in the sense of an arrangement that is at least partially stacked on top of one another. The at least partially overlapping arrangement is achieved in that the at least one second spring element is connected to the rotation body on one side and is fixed on one side. In this case, the arrangement of the first spring element within the rotation body can be designed as above, namely connected to the rotation body on one side and fixed on one side. In this way, rotary movements or actuators or sensors with rotary elements can advantageously be implemented.

The advantageous embodiments and developments of the present invention explained above and/or below can be used individually or also in any combination with one another, except for example in cases of clear dependencies or incompatible alternatives.

The above-described properties, features, and advantages of the present invention and the way in which they are achieved become clearer and more readily comprehensible in connection with the following description of exemplary embodiments, which are explained in more detail in connection with the figures.

### BRIEF DESCRIPTION OF THE DRAWINGS

FIG. 1 is a schematic representation of a micromechanical speaker, according to an example embodiment of the present invention.

FIG. 2 is a schematic representation of the micromechanical structure in FIG. 1 with at least one movable bending unit, according to an example embodiment of the present invention.

FIGS. 3A and 3B are schematic representations of a first embodiment of the movable bending unit in FIG. 2, according to the present invention.

FIG. 4 is a schematic representation of a second example embodiment of the movable bending unit in FIG. 2, according to the present invention.

FIG. 5 is a schematic representation of a third example embodiment of the movable bending unit in FIG. 2, according to the present invention.

FIG. 6 is a schematic representation of a fourth example embodiment of the movable bending unit in FIG. 2.

FIGS. 7A and 7B are schematic representations of a fifth example embodiment of the movable bending unit in FIG. 2 with an electrostatically actuatable actuating element, according to the present invention.

FIG. 7C to 7F are further schematic representations for electrostatically actuatable actuating elements shown in FIGS. 7A and 7B.

FIG. 8 is a schematic representation of a sixth example embodiment of the movable bending unit in FIGS. 7A and 7B, according to example embodiments of the present invention.

FIG. 9A to 9C are schematic representations for pneumatically actuated actuating elements, according to example embodiments of the present invention.

FIG. 10 is a schematic representation of a seventh example embodiment of the movable bending unit in FIG. 2, according to the present invention.

FIG. 11A to 11C are further schematic representations of actuating elements which can be actuated piezoelectrically by means of PZT and/or thermally by means of bimetallic strips or shape memory alloy, according to example embodiments to the present invention.

FIGS. 12A and 12B are further schematic representations for an electrostatically actuatable actuating element, according to example embodiments of the present invention.

FIG. 13 is a schematic representation of an eighth embodiment of the movable bending unit in FIG. 2.

FIG. 14A to 14E are schematic representations of spring characteristic curves for spring elements in a force-displacement diagram.

FIG. 15A to 15C are schematic representations of a ninth to eleventh example embodiments of the movable bending unit of the present invention.

### DETAILED DESCRIPTION OF EXAMPLE EMBODIMENTS

The figures are merely schematic and are not true to scale. In this sense, components and elements shown in the figures may be shown exaggeratedly large or reduced in size for better understanding. It is also pointed out that the reference signs in the figures have been selected to be unchanged for elements and/or components that are designed identically.

The subject matter of the present application is laterally actuated and/or rotationally actuated bending elements (lamellae or spring elements), comprising bending elements with, e.g., linear and non-linear spring characteristic curves, which comprise an inflection point in the force-displacement diagram when deflected together. Due to the appropriate dimensioning of the bending elements (connection of curved and/or folded elements or spring elements), the spring characteristic curve can be varied in the vicinity of this range. In this way, the spring characteristic curve can be designed to be almost linear and with a small gradient in a wide range about the inflection point. Usually, sensors and actuators are configured to operate in a linear stiffness range. If a MEMS speaker of this type—i.e., with laterally arranged bending elements (spring elements)—is brought into this range by a pre-deflection and operated, the force required for actuation is low or large movement amplitudes—correspondingly high sound power levels—can be achieved with small forces.

Advantageously, the spring stiffness is reduced by the pre-deflection to values that are required for the function or functional operation of the micromechanical structure.

The core of the present invention includes bending lamellae or spring elements assembled in this way along with elements for their temporary or permanent pre-deflection. If such combined lamellae or spring elements can be temporarily or permanently pre-deflected, it is advantageous to realize operation (deflections) of the MEMS structure in the range of low spring stiffness with a spring characteristic curve profile that is as linear as possible. With the low spring stiffness that can be achieved in this way, large movement amplitudes (and high sound power in the case of MEMS speakers) can be achieved with small actuator forces.

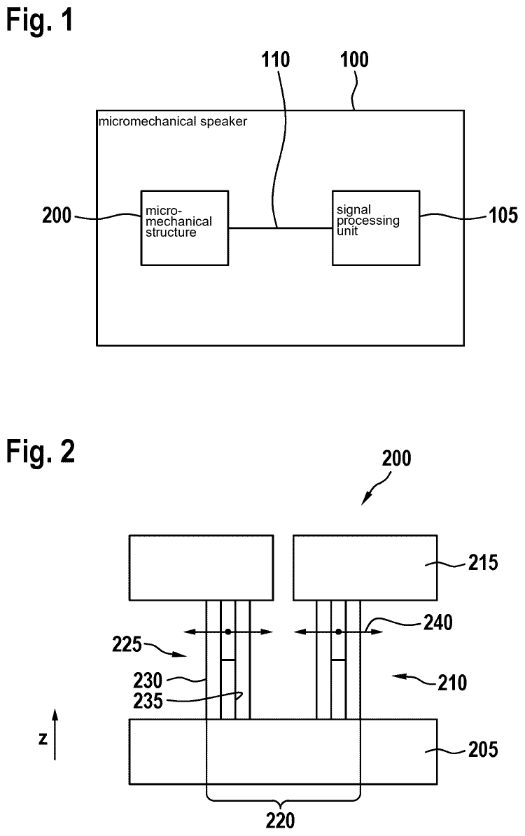

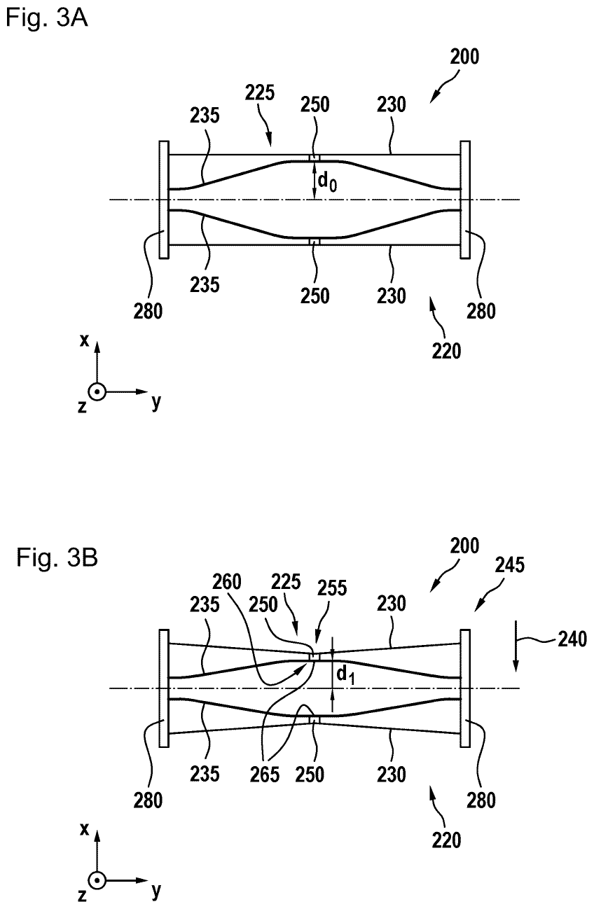

FIG. 1 is a highly simplified schematic representation of a micromechanical speaker 100. The micromechanical speaker 100 comprises a micromechanical structure 200, for example a MEMS structure (MEMS: micro electromechanical system), which is functionally actuatable to generate sound. Furthermore, the micromechanical speaker 100 comprises a signal processing unit 105. The signal processing unit 105 can, for example, be designed as an ASIC and be configured to apply and process signals from the micromechanical structure 200. In this case, the application and processing of signals, for example the application of an electrical voltage to the micromechanical structure 200 or to components of the micromechanical structure 200 such as electrodes, etc., can mean the generation of sound by compressing air by means of a movable membrane or an alternatively designed bending unit that, e.g., comprises a plurality of bending elements. The application and processing of signals may also mean the provision of a magnetic field 20, which is shown in a subsequent embodiment. Furthermore, the application and processing of signals can mean the functional operation (i.e., to generate sound) of the bending elements or bending actuators, wherein, for this purpose, signals are used which comprise a constant offset (with corresponding polarity for the pre-deflection), which are additionally modulated with signals that are intended for generating the acoustic sound. The signal processing unit 105 can therefore be regarded as a control unit. The bending unit mentioned is shown in more detail in FIG. 2.

The larger the volume of compressed air, i.e. the surface area or the amplitude of movement of the membrane (in the case of vertical deflection) or lamella (in the case of lateral deflection) with the frequencies corresponding to the desired tones, the greater the acoustic performance of the micromechanical speaker 100. The sound pressure level is a measure of the sound power, which is proportional to the square of the sound pressure. In the case of MEMS speakers, the achievable deflection is limited by the limited force of the elements or components. The deflection of the membrane or lamella is usually proportional to the force over a wide range. The proportionality constant is the spring constant or stiffness of the membrane or lamella. The stiffness is a function of, among other things, the membrane or lamella geometry (substantially thickness/height, diameter/length) and the elastic modulus of the material. The stiffness of the membrane/lamellae determines their resonance frequency.

The micromechanical structure 200 and the signal processing unit 105 can be operatively connected to one another via the connection 110, wherein the connection 110 mentioned can correspond to an electrical connection, which can be implemented, for example, as a bonding wire. Alternative embodiments are also possible.

In the schematic representation in FIG. 1, the micromechanical component 200 and the signal processing unit 105 are shown next to one another, for example. However, the micromechanical speaker 100 is not limited to this arrangement, but can also comprise the signal processing unit 105 and the micromechanical component 200 in the form of a stacked or layered arrangement one above the other. In addition, further components and/or operative (electrical) connections 105 that are not included in the simplified representation in FIG. 1 can be provided.

FIG. 2 is a more detailed schematic representation of the micromechanical structure 200 in FIG. 1 with at least one movable bending unit 220 and a plurality of bending elements 225, which can be designed as laterally 240 pre-deflectable spring elements 230, 235 (and/or rotationally pre-deflectable spring elements, not shown). The micromechanical structure 200 comprises, in the schematic representation in FIG. 2, a first layer 205, a second layer 210 and a third layer 215, wherein, for example, the second layer 210 can comprise the at least one movable bending unit 220 and can be embedded between the first layer 205 (e.g., as a silicon bottom wafer) and the third layer 215 (as a cover wafer with a plurality of openings or slots). The first to third layers 205, 210, 215 can, for example, be stacked or layered in the z-direction.

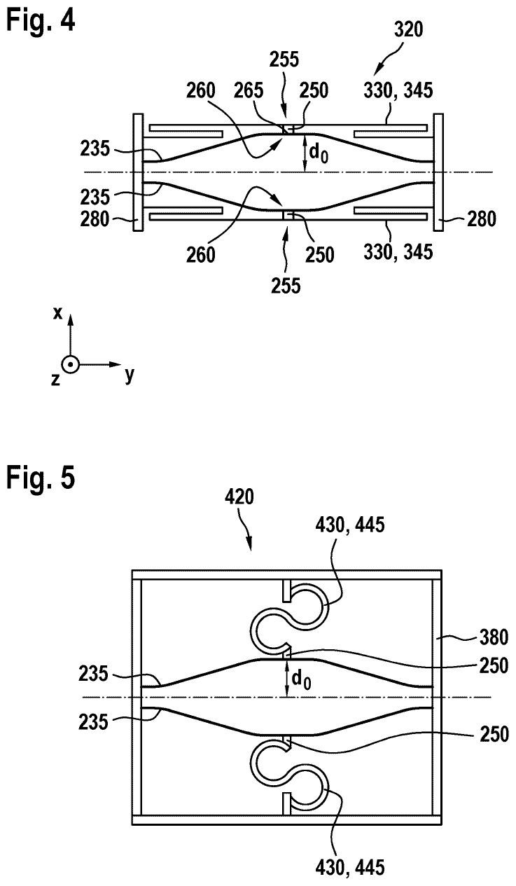

FIGS. 3A and 3B are schematic representations of a first embodiment of the movable bending unit 220 in FIG. 2. As mentioned, the at least one movable bending unit 220 can comprise a plurality of bending elements 225 designed as spring elements 230, 235. A first spring element 230 can, e.g., comprise a linear spring constant in an associated force-displacement diagram, and a second spring element 235 can, e.g., comprise a non-linear spring constant. The first spring element 230 and the second spring element 235 can in each case be fastened to a fastening element 280 on both sides. The fastening element 280 can be designed to be immovable. The first spring element 230 and the second spring element 235 can in each case be functionally actuated to generate sound, i.e. to compress the air, and can be laterally pre-deflected 240 for this purpose.

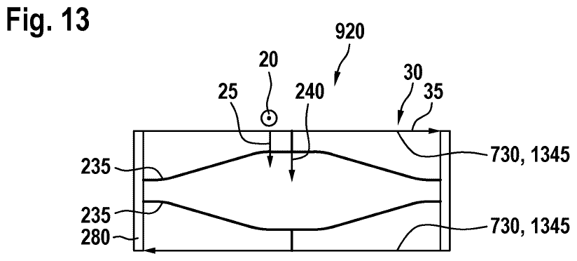

The first spring element 230 and the second spring element 235 are pre-deflected laterally 240 by means of at least one actuating element 245 in order to set the common spring characteristic curve for a functional operation of the micromechanical structure (i.e., for example for sound generation), wherein the actuating element 245 in FIG. 3B, for example, can designed similarly to the actuating element 245 in FIGS. 12A and 12B. With the aid of the actuating element 245, a temporary or permanent lateral pre-deflection 240 of the micromechanical structure 200 can be achieved. The actuating element 245 shown in FIG. 3A, 3B and FIGS. 12A and 12B can be designed as an electrostatically actuable actuating element 245.

For this purpose, the electrostatically actuatable actuating element 245 can be embedded in the first spring element 230 and designed in the form of an NED actuator (NED: nanoscopic electrostatic drive). Here, embedded means that the NED actuator is integrated into the first spring element, i.e. into the volume of the first spring element 230. This means that the first spring element 230 can comprise an electrode pair (not shown) that, when an electrical voltage is applied, leads to the formation of an electric field between the electrode pair and thus an electric force, wherein the electric force initiates a lateral movement/deformation/bending of the first spring element 230 and thus can effect a lateral pre-deflection 240, as shown in FIGS. 3B and 12B.

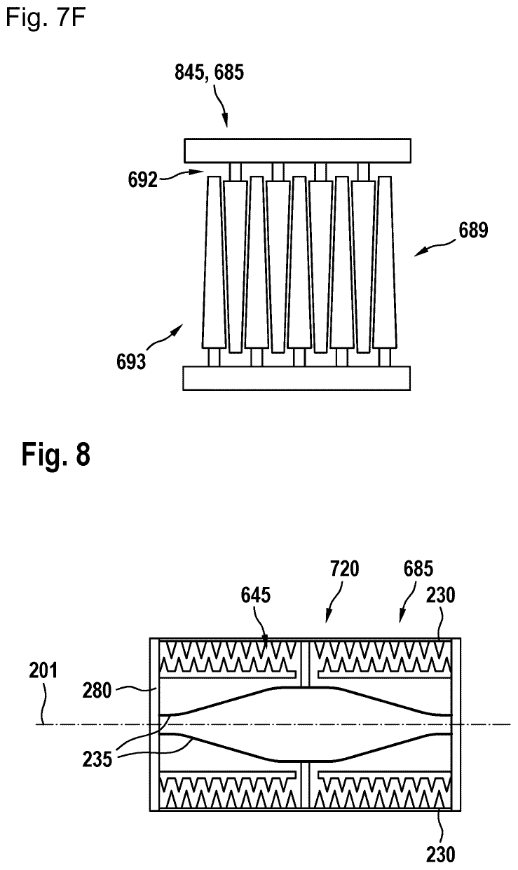

In FIG. 7A to 7F, further electrostatically actuatable actuating elements are also shown, which are designed, for example, as separate actuating elements. Alternatively, it is also possible to integrate these into the first spring element 230 and/or the second spring element 235. The following figures show further embodiments of actuating elements or further actuation types for the actuating elements. The actuating elements for the pre-deflection must effect a deflection without negatively influencing the mobility and the resilient properties of the overall structure, i.e. the bending unit 220 or the MEMS structure 200.

In FIG. 3A the rest position do of the first and second spring elements 230, 235 is shown. FIG. 3B, however, shows the lateral 240 pre-deflection di-do of the first and second spring elements 230, 235 as explained above. The first spring element 230 and the second spring element 235 are mechanically coupled 250, such that their common spring characteristic curve comprises an inflection point 270 in the force-displacement diagram. The mechanical coupling 250 can, e.g., be carried out in such a way that a central portion of the first spring element 255 is connected to a central portion of the second spring element 260 with the aid of a connecting element 265. The connecting element 265 can also be made of silicon. Alternatively, it is possible to use different materials.

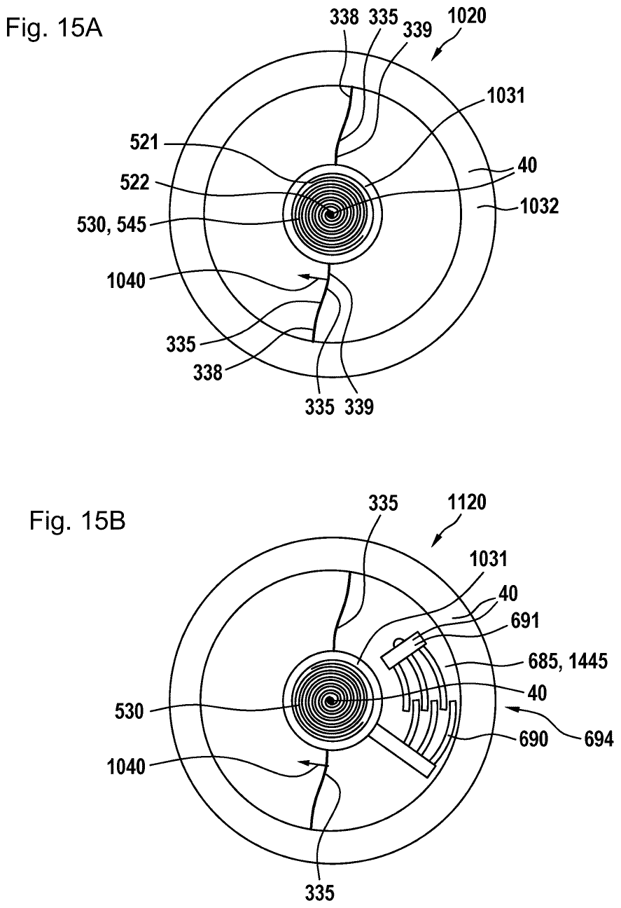

The common spring characteristic curve can comprise a degressive-horizontal-progressive profile, as shown in FIG. 14D, i.e. comprise an inflection point 270 and an approximately linear region 275 about the inflection point 270. The approximately linear region 275 or the approximately horizontal region should have a slight (or small) gradient, which is suitable for the operation of the speaker 100 and which makes possible large deflections of the spring elements 230, 235 or the lamellae with small actuator forces. Further spring characteristic curves by way of example for spring elements are shown in FIGS. 14A to 14C and 14E.

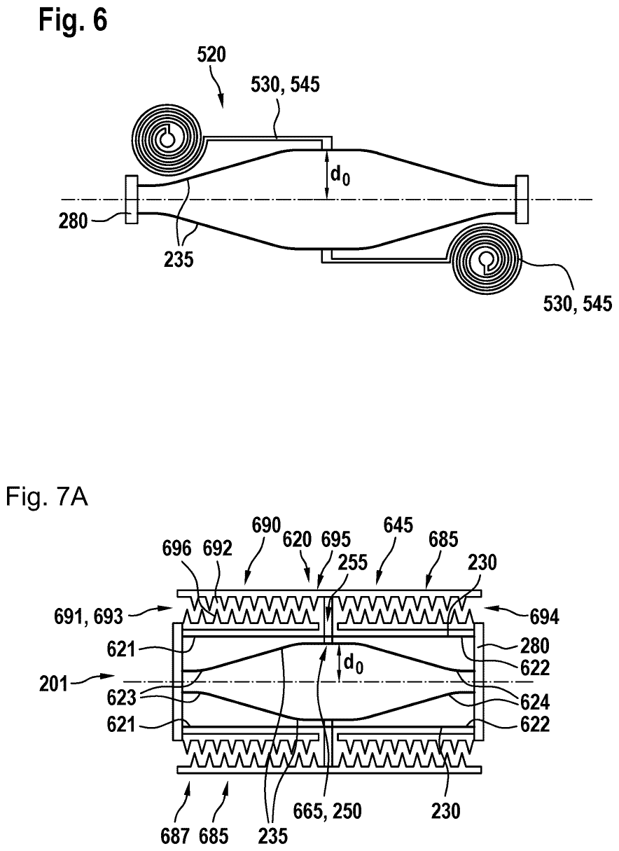

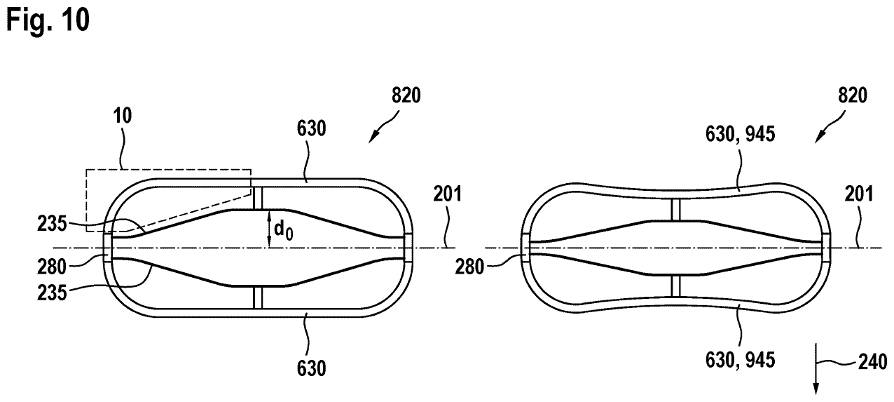

FIGS. 4 to 6 in each case are schematic representations of bending units according to a second to fourth embodiment 320, 420, 520. Since the bending units 320, 420, 520 shown in FIGS. 4 to 6 in each case correspond to examples of pneumatically actuatable actuating elements 345, 445, 545, and the pneumatically actuatable actuating elements 345, 445, 545 are shown individually in FIG. 9A to 9C, the figures mentioned will be described together. As pneumatically actuatable actuating elements 345, 445, 545, e.g. in each case laterally at least partially curved or folded tube springs are used, which are designed as a first spring element 330, 430, 530 and/or as a second spring element 235 or are attached to the first spring element 330, 430, 530 and/or the second spring element 235 or are connected to the first spring element 330, 430, 530 and/or the second spring element 235. In the representations of FIGS. 4 to 6, in each case the tube spring is designed as the first spring element 330, 430, 530. Alternatively, the variants mentioned above are also possible, which are not explicitly shown in the figures.

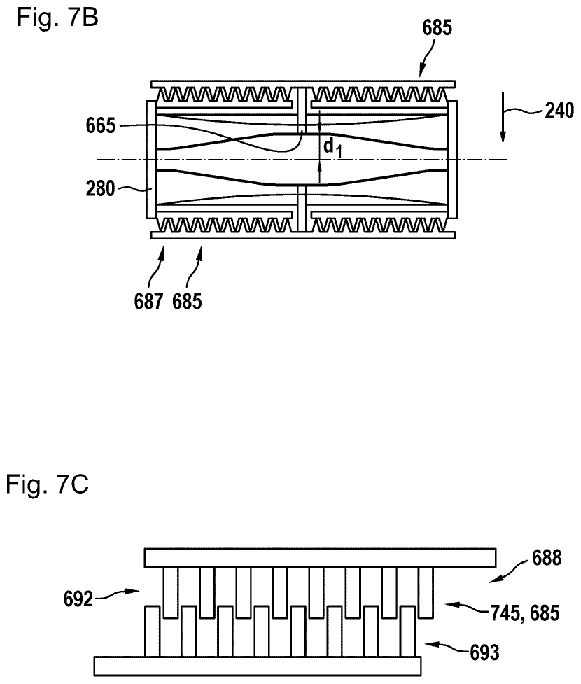

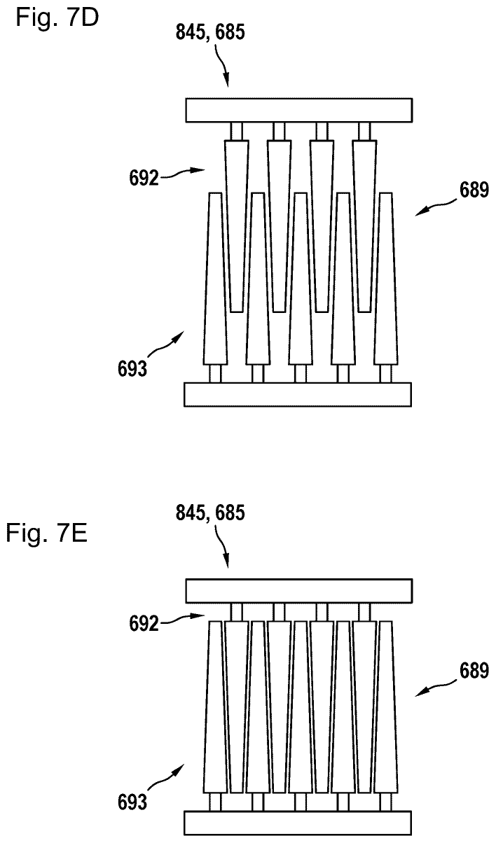

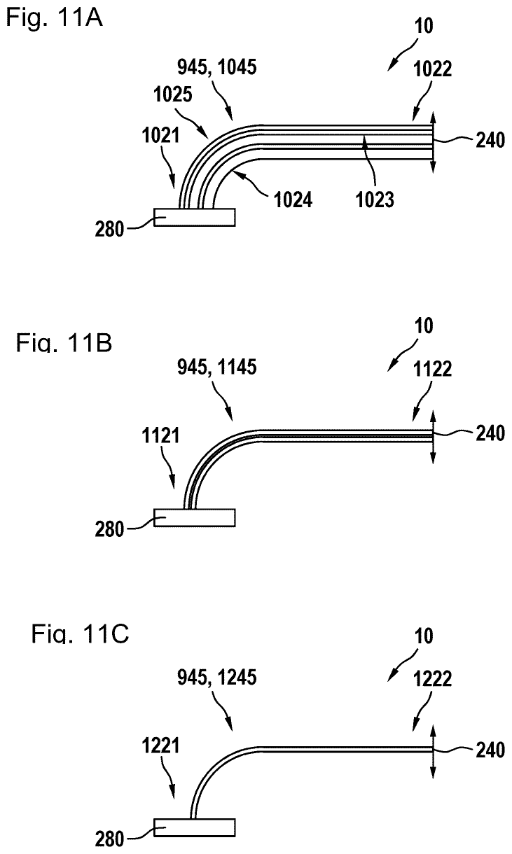

The tube springs can be designed to be folded (FIG. 4 and FIG. 9A), S-shaped (FIG. 5 and FIG. 9B) or spiral-shaped (FIG. 6 and FIG. 9C). In addition, it is also possible that the tube spring is formed linearly with rounded edges or curved edges and is embedded in the first spring element 630, as shown in the representation in FIG. 10. The principle of pneumatic actuation is based on the creation of a pressure difference between an inner volume of the laterally at least partially curved or folded tube spring and an outer volume of the tube spring, which leads to a movement of the tube spring, in order to effect the lateral pre-deflection 240 of the first spring element 330, 430, 530, 630 and/or the second spring element 235. In MEMS speakers 100, a negative pressure (vacuum) is preferably set in the tube spring. For this purpose, the inner volume of the tube spring can be evacuated and sealed during completion, for example by means of “laser reseal.”

In order to make the fastening of the first spring element 430 on both sides possible, in which the pneumatically actuatable actuating element 445 is embedded as an S-shaped tube spring in FIG. 5, and of the second spring element 235 to the fastening element 380, the fastening element 380 in FIG. 5 is designed, for example, to be frame-shaped or frame-like and encloses or surrounds the first spring element 430 and the second spring element 235 on the inside.

FIGS. 7A and 7B are schematic representations of a fifth embodiment of the movable bending unit 620 with an electrostatically actuatable actuating element 645. In the representation in FIGS. 7A and 7B, the first spring element 230 is in each case fixed to the fastening element 280 at a first and second end of the first spring element 621, 622. Likewise, the second spring element 235 is in each case fixed to the fastening element 280 at a first and second end of the second spring element 623, 624. The electrostatically actuatable actuating element 645 is designed in FIGS. 7A and 7B in the form of an electrode pair 685. The electrode pair 685 can be arranged above the first spring element 230 and/or below the first spring element 230 and/or between the first and second spring elements 230, 235 and connected to the first spring element 230 and/or to the second spring element 235. In the representation in FIGS. 7A and 7B, the electrode pair 685 is arranged above the first spring element 230 and below the first spring element 230. The connection of the electrode pair 685 to the first spring element 230 and/or to the second spring element 235 can be made via a connecting element 665. In this case, FIGS. 7A and 7B in each case show a connection of the electrode pair 685 to the first spring element 230 and a connection of the electrode pair 685 to the second spring element 235, in each case using the connecting element 665.

When an electrical voltage is applied to the electrode pair 685, an electrical force is generated (not shown), which acts attractively on the electrode pair 685 and deflects the electrode pair 685 from a rest position 694, in order to effect a lateral pre-deflection 240 of the first spring element 230 and/or the second spring element 235 due to the connection of the electrode pair 685 to the first and/or second spring element 230, 235. In the example shown, the electrode pair 685 is designed to engage with one another. The first electrode 690 of the electrode pair 685 is designed to be, for example, movable, and the second electrode 691 of the electrode pair 685 is, for example, fixed. When an electrical voltage is applied to the first and second electrodes 690, 691, an attractive electrical force is generated on the electrode pair 685, which leads to a movement of the first electrode 690 in the direction of the second electrode 691. Due to the use of the connecting element 665, which is connected to the first electrode 690 and the first spring element 230 along with the second spring element 235, it is finally possible to deflect the two spring elements 230, 235 laterally.

The first electrode 690 of the electrode pair 685 comprises a plurality of projections 692 on a first side 695 facing the second electrode 691 of the electrode pair 685. The second electrode 691 of the electrode pair 685 comprises, on a first side 696 facing the first electrode 690 of the electrode pair 685, a plurality of projections 693, which are arranged offset from the plurality of projections 692 on the first side 695 of the first electrode 690. The plurality of projections 692 of the first electrode 690 and the plurality of projections 693 of the second electrode 691 are designed to be tooth-like 687 (or wedge-like) or edge-like 688 or truncated cone-like 689. Here, FIGS. 7A and 7B are an example of a tooth-like 687 plurality of projections 692, 693 of the first and second electrodes 690, 691. The electrode pair 685 shown can in particular form an interdigital electrode pair.

Alternatively, it would be possible to use an electrode pair 685 arranged only on one side, provided that the first spring element 230 and the second spring element 235 are also formed only on one side. In the representation shown, the first spring element 230 and the spring element 235 are in each case formed symmetrically along a plane of symmetry 201. It is understood that the symmetrical design also applies to the preceding and similarly designed subsequent exemplary embodiments, wherein it is possible that the already explained exemplary embodiments also in each case comprise spring elements 230, 235 formed only on one side, which can then in each case be deflected forward only by a single actuating element.

The electrical force acting on the electrode pair 685 has an attractive, i.e. pulling, effect, as mentioned above. In this way, a unidirectional actuation or pre-deflection of the spring elements 230, 235 can be carried out. If the electrode pair 685 were arranged to act in opposite directions, a bidirectional actuation or pre-deflection of the spring elements 230, 235 could alternatively be made possible.

FIG. 7C to 7F are further schematic representations for electrostatically actuatable actuating elements 745, 845, which are shown in FIGS. 7A and 7B. The actuating elements 745, 845 of FIG. 7C to 7F can also be designed in the form of an electrode pair 685, for example as interdigital electrodes. FIG. 7C shows an example of an edge-shaped 688 plurality of projections 692, 693. FIG. 7D to 7F in each case show examples of a truncated cone-shaped 689 plurality of projections 692, 693. In this case, the truncated cone-shaped 689 plurality of projections has the advantage of a self-limiting effect on the electrode pair, i.e. in contrast to the other tooth-like 687 or edge-shaped 688 designs of the plurality of projections 692, 693, which will attract one another until they “snap together,” the truncated cone-shaped 689 design can prevent this effect. The mutual snapping together can also be referred to as so-called “electrostatic collapse” and can occur at the distance at which the electrical force (electrostatic force) exceeds the linear restoring force of the spring elements 230, 235.

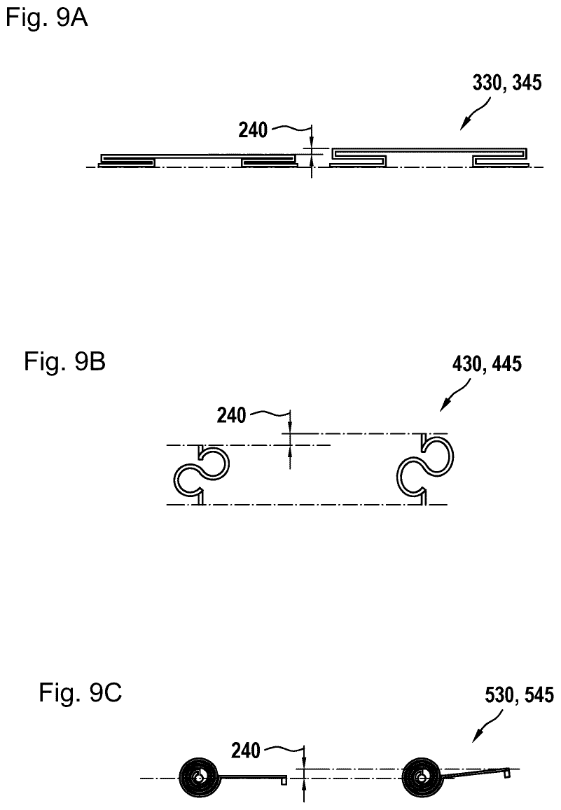

FIG. 8 is a schematic representation of a sixth embodiment of the movable bending unit 720 in FIGS. 7A and 7B. In contrast to FIGS. 7A and 7B, the electrode pair 685 is arranged as an electrostatically actuatable actuating element 645, here between the first and second spring elements 230, 235. The electrode pair 685 can also be designed as an interdigital electrode pair and, in the representation, comprises, e.g., a tooth-like 687 plurality of projections 692, 693.

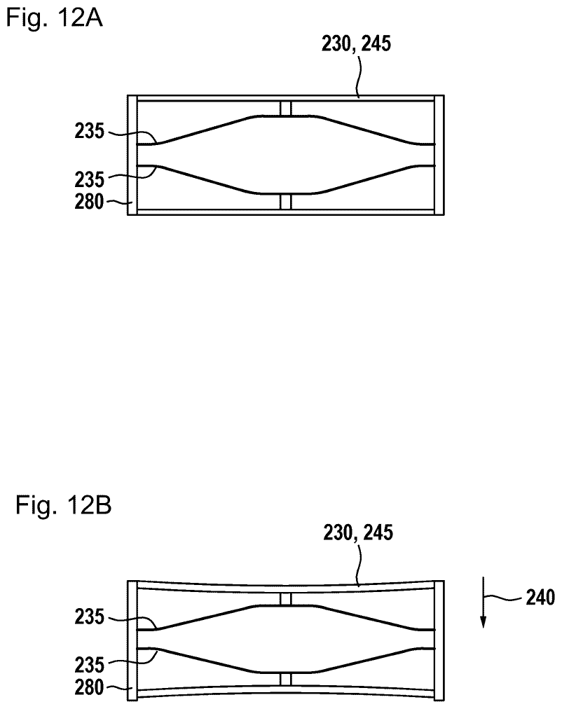

As mentioned above, the laterally at least partially curved or bent tube spring can, e.g., also be formed linearly with rounded edges or with bent edges and form the first spring element 630, as shown in FIG. 10. Alternatively, it is also possible that the geometry of the first spring element 630 can be selected in such a way, i.e. with curved or rounded edges. A section 10, shown in dashed lines, for further embodiments of an actuating element 945 for the pre-deflection or for the functional actuation/functional deflection, which can be attached to the first spring element 630 of a bending unit 820 and/or can form a first spring element 630 of a bending unit 820, is shown in more detail in the following FIG. 11A to 11C.

FIG. 11A shows an exemplary embodiment of a piezoelectrically actuatable actuating element 1045, which can be attached, e.g., to the first spring element 630 in the section 10 in FIG. 10 and can effect a lateral pre-deflection 240 (and/or rotational pre-deflection, not shown) of the first spring element 630 and/or the second spring element 235. For example, a piezoelectric strip pair 1023 can be used as the piezoelectrically actuatable actuating element 1045, which is arranged on the first spring element 630 and/or on the second spring element 235 or is connected to the first spring element 630 and/or to the second spring element 235. In the example shown in FIGS. 10 and 11A, the piezoelectric strip pair 1023 can be arranged as an actuating element 1045 on the first spring element 630 (for example, for this purpose, opposing PZT strips can be attached to a surface of the first spring element 630 as a piezoelectric strip pair 1023). A first end 1021 of the piezoelectric strip pair 1023 can be designed to be fixable, and/or a second end 1022 of the piezoelectric strip pair 1023 can be designed to be movable. In the example shown, the first end 1021 of the piezoelectric strip pair 1023 is designed to be fixed and the second end 1022 of the piezoelectric strip pair 1023 is designed to be movable, in order to effect a lateral pre-deflection 240. It is understood that the piezoelectric strip pair 1023, as the actuating element 1045, can be attached not only in the section 10 in FIG. 10 on the first spring element 630, but can also be attached oppositely on the plane of symmetry 201 on the first spring element 630, and can be attached along the section 10 (also mirrored on the plane of symmetry 201 along the section 10) on the first spring element 630.

When an electrical voltage of opposite polarity is applied to the piezoelectric strip pair 1023 (not shown), the piezoelectric strip pair 1023 is configured to perform an extension movement/dilation 1025 and/or compression movement/contraction 1024, in order to effect a lateral pre-deflection 240 (and/or rotational pre-deflection, not shown) of the first spring element 630 and/or of the second spring element 235. In the representation in FIGS. 10 and 11A, the first spring element 630 and the second spring element 235 are deflected laterally 240 with the aid of the piezoelectrically actuatable actuating element 1045. Here, the lateral pre-deflection 240 can be temporary. A rotational pre-deflection can also be temporary.

Furthermore, FIG. 11B shows an exemplary embodiment of a thermally actuatable actuating element 1145, which can be attached, e.g., in the section 10 in FIG. 10 to the first spring element 630, and can effect a lateral pre-deflection 240 (and/or a rotational pre-deflection, not shown) of the first spring element 630 and/or the second spring element 235. For this purpose, a bimetallic strip, e.g., can be used as the thermally actuatable actuating element 1145. The bimetallic strip can be attached to the first spring element 630 and/or to the second spring element 235 or connected to the first spring element 630 and/or to the second spring element 235. A first end of the bimetallic strip 1121 can be designed to be fixable, and/or a second end of the bimetallic strip 1122 can be designed to be movable. In the representation in FIG. 11B, the first end of the bimetallic strip 1121 is designed to be fixed and the second end of the bimetallic strip 1122 is designed to be movable. When heated, the bimetallic strip is configured to perform a movement, in order to effect a lateral pre-deflection 240 of the first spring element 630 and/or the second spring element 235. The heating of the bimetallic strip can be achieved either by short-circuiting the bimetallic strip or by using a heating element (not shown). In the embodiment shown, the change in temperature of the bimetallic strip effects a movement of the strip and a resulting lateral pre-deflection 240 of the first spring element 630 and the second spring element 235. Here, the lateral pre-deflection 240 can be temporary. A rotational pre-deflection can also be temporary.

A further alternative for a thermally actuatable actuating element 1245, which can be embedded in the section 10 in FIG. 10 in the first spring element 630, and can effect a lateral pre-deflection 240 (and/or rotational pre-deflection, not shown) of the first spring element 630 and/or the second spring element 235, is shown in FIG. 11C. For this purpose, a shape memory alloy is used as the thermally actuatable actuating element 1245, which shape memory alloy is attached to the first spring element 630 and/or to the second spring element 235 or is connected to the first spring element 630 and/or to the second spring element 235. A first end of the shape memory alloy 1221 can be designed to be fixable, and/or a second end of the shape memory alloy 1222 can be designed to be movable. In the representation in FIG. 11C, the first end of the shape memory alloy 1221 is designed to be fixed and the second end of the shape memory alloy 1222 is designed to be movable.

The shape memory alloy can be configured to undergo a phase transition upon heating (for example by means of a heating element, not shown), wherein the phase transition brings about a structural change of the shape memory alloy, in order to effect a lateral pre-deflection 240 (and/or a rotational pre-deflection, not shown) of the first spring element 630 and/or the second spring element 235. In the embodiment shown, the change in the temperature of the shape memory alloy effects a structural change of the alloy, i.e. deformation of the alloy, and a resulting lateral pre-deflection 240 of the first spring element 630 and the second spring element 235. Here, the lateral pre-deflection 240 can be permanent. A rotational pre-deflection can also be permanent.

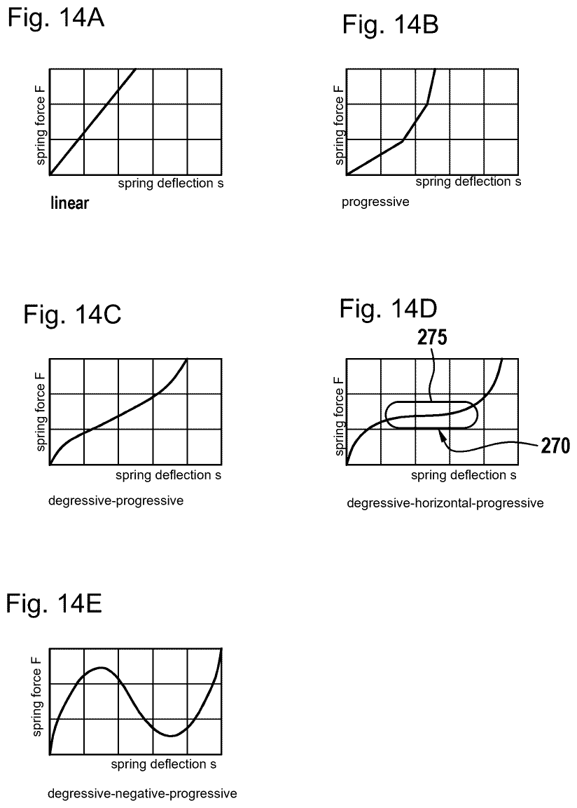

FIG. 13 is a schematic representation of an eighth embodiment of the movable bending unit 920 in FIG. 2 with a magnetically actuatable actuating element 1345. A busbar 30 or a current loop or a conductor track made of electrically conductive material (metal material such as copper or an alternative) in a magnetic field 20 can be used as the magnetically actuatable actuating element 1345. The magnetic field 20 can, e.g., protrude from the plane of the drawing. The busbar 30 can be attached to the first spring element 730 and/or to the second spring element 235 or connected to the first spring element 730 and/or to the second spring element 235. In the representation in FIG. 13, the busbar 30 is attached to the first spring element 730. When an electrical voltage is applied to the busbar 30 (not shown), a current flow (moving charge carriers) is generated, which, in the magnetic field 20, generates a magnetic force/Lorentz force 25 on the busbar 30 or on the moving charge carriers, and effects a lateral pre-deflection 240 (and/or a rotational pre-deflection, not shown) of the first spring element 730 and/or the second spring element 235.

In the representation in FIG. 13, a current flow direction 35 or a movement direction of the charge carriers 35 can be carried out, e.g. in the direction of the arrow shown, the magnetic field 30 can protrude from the plane of the drawing, and a direction of the Lorentz force 25 can be determined, e.g. using the right-hand rule as shown (thumb: current flow direction 35, i.e. technical current direction of the positive charge, index finger: direction of the magnetic field 20, and middle finger: direction of the Lorentz force 25). The Lorentz force 25 acts (as viewed from the first spring element 730) in the direction of the second spring element 235 and accordingly leads to a lateral pre-deflection 240 of the first spring element 730 and the second spring element 235 in the direction illustrated, wherein the direction of the pre-deflection 240 is designed to be parallel to the direction of the Lorentz force 25. Here, the lateral pre-deflection 240 can be temporary. A rotational pre-deflection can also be temporary.

The following Table 1 summarizes the properties of the different actuation options for pre-deflection. In addition, Table 1 also contains a column “functional actuation” for the functional operation of the micromechanical structure 200, e.g. to generate sound for a MEMS structure 200 designed as a micromechanical speaker 100. The (setting) direction of the functional actuation is also indicated here.

TABLE 1

| | Actuation for lateral | | Functional |
|---|---|---|---|
| | pre-deflection | Pre-deflection | actuation |
| 1 | electrostatic, | temporary | bidirectional |
| | interdigital electrodes | | |
| | (geometrically arranged | | |
| | to effect an opposingly | | |
| | acting force) | | |
| 2 | pneumatic | permanent | no |
| 3 | piezoelectric | temporary | bidirectional |
| 4 | nano-electric drive | temporary | unidirectional |
| | (NED) | | |
| 5 | magnetic | temporary | no |
| 6 | thermal (e.g., via | temporary | no |
| | bimetal spring) | | |
| 7 | thermal (e.g., via | permanent | no |
| | shape memory alloy) | | |

The actuating elements 245, 345, 445, 545, 645, 745, 845, 945, 1045, 1145, 1245, 1345, 1445 for the pre-deflection (actuators or bending actuators) can be integrated into both the first (linear) spring element 230, 330, 430, 530, 630, 730 and/or the second (non-linear) spring element 235, 335, or arranged on the first spring element 230, 330, 430, 530, 630, 730 and/or on the second spring element 235, 335.

For functional actuation (e.g., for generating sound), electrostatic 245, 645, 745, 845 and/or piezoelectric 1045 and/or magnetic 1345 actuating elements (bending actuators) can be attached to the second spring element 235, 335 and/or integrated or embedded in the second spring element 235, 335 or connected to the second spring element 235, 335. Electrostatic interdigital electrodes as the electrode pair 685 can also be attached to the connecting element 265 between the first (linear) spring element 230, 630, 730 and the second (non-linear) spring element 235, 335. The functional actuators and the actuating elements 245, 645, 745, 845, 1045, 1345 for the pre-deflection can interact. Depending on the properties of the actuators, the interaction can be carried out in a synchronous and rectified manner and makes increased deflection possible.

Actuating elements according to numbers 1, 3, 4 and 5 in Table 1 can in principle be used for both lateral pre-deflection and also functional actuation. In this case, the functional operation of the actuators (e.g., for generating sound) can be carried out with signals that comprise a constant offset (with corresponding polarity for the pre-deflection), which are additionally modulated with signals intended for generating the acoustic sound. This means that functional actuation can be carried out by means of an electrostatically actuatable 245, 645, 745, 845 and/or piezoelectrically 1045 actuatable and/or magnetically 1345 actuatable actuating element, wherein an above-mentioned signal can be modulated onto the micromechanical structure 200.

The actuating elements 245, 345, 445, 545, 645, 745, 845, 945, 1045, 1145, 1245, 1345, 1445 can be used in all constellations on/in the first (linear) spring element 230, 330, 430, 530, 630, 730 and/or on/in the second (non-linear) spring element 235, 335. Here, the following constellations are possible:
1. A temporarily acting actuating element for pre-deflection and functional actuation
2. Two temporarily acting actuating elements, both for pre-deflection and functional actuation
3. Two temporarily acting actuating elements-one for pre-deflection and the second for the functional actuation
4. Two actuating elements-one for permanent pre-deflection and the second for the functional actuation.

If a temporarily acting actuating element 245, 645, 745, 845, 1045, 1145, 1345 is used for the pre-deflection, different operating points in the spring characteristic curve field of the combined or mechanically coupled first and second spring elements 230, 235, 335, 630, 730 with different spring stiffnesses and thus different resonance frequencies of the MEMS speaker 100 can be set via the degree of pre-deflection.

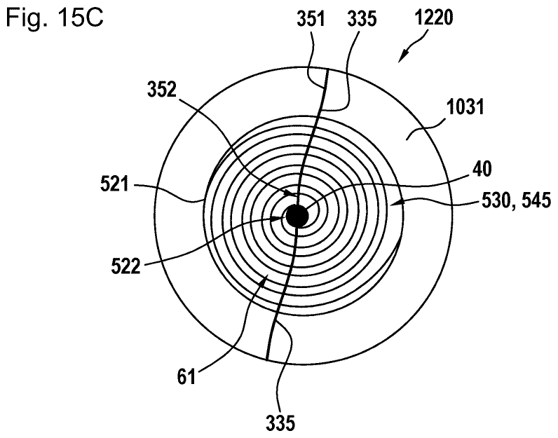

FIG. 15A to 15C are schematic representations of a ninth to eleventh embodiment of the movable bending unit 1020, 1120, 1220, wherein, here in particular, the movable bending unit 1020, 1120, 1220 is in each case designed as a rotation unit with a rotation body 1031 and a rotational deflection 1040 or a rotary movement is made possible. The rotation body 1031 in FIGS. 15A and 15B is designed to be substantially circular and movable. In this case, substantially circular can mean having at least an approximately circular shape, up to having a circular shape. In the example shown, the rotation body 1031 comprises a circular shape.

The first spring element 530 is arranged within the rotation body 1031, wherein the first spring element 530 is connected to the rotation body 1031 on one side 521 and fixed 40 on one side 522. The first spring element 530 is designed as a pneumatically actuatable, at least partially curved or folded, tube spring for the rotational pre-deflection of the first spring element 530 and/or of the at least one second spring element 335. In the example shown, the tube spring is designed to be spiral-shaped and forms the first spring element 530. Alternative geometric designs of the tube spring, such as in the previous figures, are also possible. The at least one second spring element 335 is connected on one side 339 to the rotation body 1031 and on one side 338 to a fixing element 1032. The fixing element 1032 is designed to be immovable and is designed to be, e.g., also circular in the representation. However, the geometric shape of the fixing element 1032 can also be implemented alternatively to the example shown.

The bending unit 1020 in FIG. 15A can be pre-deflected rotationally 1040 with the aid of the spiral-shaped tube spring as the first spring element 530 or pneumatically actuatable actuating element 545. In this case, the principle of pneumatic actuation can be carried out as explained above, wherein the movement of the tube spring in the exemplary embodiment shown can lead to a rotational pre-deflection 1040 of the first spring element 530 and of the movable rotation body 1031 connected to the first spring element 530, as well as of at least one second spring element 335 connected in each case on one side 339 to the rotation body 1031, since the geometry of the bending unit 1020 designed as a rotation unit with the rotation body 1031 has been selected accordingly for a feasible rotational or rotary movement.

Here, the rotary pre-deflection 1040 of the spiral-shaped tube spring, which forms the first spring element 530, can be carried out, e.g., permanently. The pre-deflection 1040 can contribute to the restoring force of the first spring element 530 and of the second spring element 335 in the common spring characteristic curve subsequently being reduced, and a rotary movement of the rotation unit with a reduced restoring force being made possible as a result of the pre-deflection 1040. In this way, rotary actuators and/or sensors can also be provided. As an alternative to the described tube spring as the actuating element 545, the above-described actuating elements for a lateral pre-deflection 240 can also be integrated into the bending units 1020, 1120, 1220 of FIG. 15A to 15C, in order to effect a rotational pre-deflection here.

In contrast to FIG. 15A, in FIG. 15B an electrode pair 685, e.g. an interdigital electrode pair, is used as an electrostatically actuatable actuating element 1145 between the rotation body 1031 and the fixing element 1032. The electrode pair 685 can comprise a first, movable electrode 690 and a second, fixed electrode 691, similar to that explained above. Here, the first electrode 690 can be mechanically fastened to the rotation body 1031. For the design and functioning of the electrode pair 685, comprising the first and second electrodes 690, 691 in combination with the lateral deflection 240 (which in FIG. 15B can correspond to a rotational pre-deflection 1040 and/or a functional actuation, i.e. a setting of the functional operation of the bending unit 1120), reference is therefore made to the above explanation.

FIG. 15C shows a further embodiment of the rotation body 1031 of FIGS. 15A and 15B. In contrast to FIGS. 15A and 15B, the first spring element 530 (in the representation with a pneumatically actuatable spiral tube spring as the actuating element 545) and/or the at least one second spring element 335 are arranged 61 at least partially overlapping one another, in that the at least one second spring element 335 is connected to the rotation body 1031 on one side 351 and fixed 40 on one side 352. In this case, at least partially overlapping one another can be understood in the sense of an arrangement that is at least partially stacked on top of one another. In this case, the arrangement of the first spring element 530 within the rotation body 1031 can be designed as above, namely connected to the rotation body 1031 on one side 521 and fixed 40 on one side 522. In this way, the at least one second spring element 335 can be arranged at least partially above the first spring element 530.

Possible applications of the present invention are MEMS sensors or actuators in which elements are moved laterally, e.g.
MEMS speakers
gravimeters
scales with high sensitivity, e.g. (nano) scales
xy and/or rotary actuators with large stroke/angle, e.g. for a translational or rotational micropositioning element
energy harvesters, or
relays (monostable/bistable).

The present invention has been described in detail by means of preferred exemplary embodiments. Instead of the described exemplary embodiments, further exemplary embodiments are possible, which can comprise further modifications or combinations of described features. For this reason, the present invention is not limited by the disclosed examples since other variations can be derived therefrom by a person skilled in the art without departing from the scope of protection of the present invention.

1-18. (canceled)

19. A micromechanical structure, comprising:
at least one movable bending unit, which includes a plurality of bending elements, wherein the plurality of bending elements are deflectable spring elements;
wherein at least one first spring element of the deflectable spring elements has a linear spring constant in an associated force-displacement diagram, and/or at least one second spring element of the deflectable spring elements has a non-linear spring constant in an associated force-displacement diagram,
wherein the first spring element and/or the second spring element can be functionally actuated,
wherein the first spring element and/or the second spring element are mechanically coupled, such that their common spring characteristic curve has an inflection point in the force-displacement diagram,
wherein the first spring element and/or the second spring element are laterally and/or rotationally pre-deflected by at least one actuating element in order to set the common spring characteristic curve for functional operation of the micromechanical structure, and
wherein the at least one actuating element effects a temporary or permanent pre-deflection.

20. The micromechanical structure according to claim 19, wherein the at least one actuating element is configured to be electrostatically actuated and/or pneumatically actuated and/or piezoelectrically actuated and/or magnetically actuated and/or thermally actuated.

21. The micromechanical structure according to claim 20, wherein:
a first end and/or a second end of the first spring element is fixed,
a first end and/or a second end of the second spring element is fixed,
a central portion of the first spring element and/or a central portion of the second spring element are mechanically coupled to one another,
an electrode pair is arranged above the first spring element and/or below the first spring element and/or between the first and second spring elements as an electrostatically actuatable actuating element, which is connected to the first spring element and/or to the second spring element, and
when an electrical voltage is applied to the electrode pair, an electrical force is generated, which acts attractively on the electrode pair and deflects the electrode pair from a rest position, in order to effect a lateral and/or rotational pre-deflection of the first spring element and/or the second spring element.

22. The micromechanical structure according to claim 21, wherein:
the electrode pair is configured to engage with one another,
a first electrode of the electrode pair includes a plurality of projections on a first side facing a second electrode of the electrode pair,
the second electrode of the electrode pair includes, on a first side facing the first electrode of the electrode pair, a plurality of projections, which are arranged offset from the plurality of projections on the first side of the first electrode, and
the plurality of projections of the first electrode and the plurality of projections of the second electrode are tooth-like or edge-like or truncated cone-like.

23. The miromechanical structure according to claim 20, wherein:
the at least one actuating element includes a pneumatically actuatable actuating element which includes a laterally at least partially curved or folded tube spring which: (i) is configured as the first spring element and/or as the second spring element or (ii) is attached to the first spring element and/or to the second spring element or (iii) is connected to the first spring element and/or to the second spring element,
a pressure difference is created between an inner volume of the tube spring and an outer volume of the tube spring, which leads to a movement of the tube spring, in order to effect a lateral and/or rotational pre-deflection of the first spring element and/or the second spring element.

24. The micromechanical structure according to claim 20, wherein:
the at least one actuating element includes a piezoelectrically actuatable actuating element which includes a piezoelectric strip pair is the piezoelectrically actuatable actuating element, which: (i) is attached to the first spring element and/or to the second spring element or (ii) is connected to the first spring element and/or to the second spring element, and
when an electrical voltage of opposite polarity is applied to the piezoelectric strip pair, the piezoelectric strip pair is configured to perform an extension movement and/or compression movement, in order to effect a lateral and/or rotational pre-deflection of the first spring element and/or the second spring element.

25. The micromechanical structure according to claim 20, wherein:
the at least one actuating element includes a magnetically actuatble actuating element which includes a busbar made of electrically conductive material in a magnetic field, wherein the busbar: (i) is attached to the first spring element and/or to the second spring element or (ii) is connected to the first spring element and/or to the second spring element,
when an electrical voltage is applied to the busbar, a current flow is generated, which generates a magnetic force on the busbar in the magnetic field and effects a lateral and/or rotational pre-deflection of the first spring element and/or the second spring element.

26. The micromechanical structure according to claim 20, wherein:
the at least one actuating element includes a thermally actuable actuating element which includes a bimetallic strip, wherein the bimetallic strip: (i) is attached to the first spring element and/or to the second spring element or (ii) is connected to the first spring element and/or to the second spring element,
a first end of the bimetallic strip is configured to be fixable and/or a second end of the bimetallic strip is configured to be movable, and
the bimetallic strip is configured, when heated, to perform a movement, in order to effect a lateral and/or rotational pre-deflection of the first spring element and/or the second spring element.

27. The micromechanical structure according to claim 20, wherein:
the at least one actuating element includes a thermally actuatable actuating element which includes a shape memory alloy, wherein the shape memory alloy: (i) is attached to the first spring element and/or attached to the second spring element or (ii) connected to the first spring element and/or to the second spring element,
a first end of the shape memory alloy is configured to be fixable and/or a second end of the shape memory alloy is configured to be movable, and
the shape memory alloy is configured to undergo a phase transition upon heating, wherein the phase transition brings about a structural change of the shape memory alloy, in order to effect a lateral and/or rotational pre-deflection of the first spring element and/or the second spring element.

28. The micromechanical structure according to claim 19, wherein the at least one movable bending unit includes a rotation unit with a rotation body for a rotational pre-deflection.

29. The micromechanical structure according to claim 28, wherein:
the rotation body is substantially circular and movable,
the first spring element is arranged within the rotation body, which is connected on one side to the rotation body and fixed on one side,
the first spring element is a pneumatically actuatable at least partially curved or folded tubule spring including a spiral-shaped tubule spring, for the rotational pre-deflection of the first spring element and/or of the at least one second spring element,
the at least one second spring element is connected on one side to the rotation body and on one side to a fixing element, and
the fixing element is immovable.

30. The micromechanical structure according to claim 29, wherein:
between the rotation body and the fixing element, an electrode pair is further arranged as an electrostatically actuatable actuating element for the rotational pre-deflection of the first spring element and/or the at least one second spring element.

31. The micromechanical structure according to claim 28, wherein the first spring element and/or the at least one second spring element are arranged at least partially overlapping one another, in that the at least one second spring element is connected on one side to the rotation body and fixed on one side

32. The micromechanical structure according to claim 19, wherein a functional actuation is carried out using an electrostatically actuatable and/or piezoelectrically actuatable and/or magnetically actuatable actuating element and for this purpose a signal can be modulated onto the micromechanical structure.

33. The micromechanical structure according to claim 32, wherein the functional actuation can be set unidirectionally or bidirectionally.

34. The micromechanical structure according to claim 19, wherein the micromechanical structure is configured to be functionally actuable to generate sound, to form a micromechanical speaker.

35. The micromechanical structure according to claim 19, wherein the micromechanical structure is configured to be functionally actuatable for use as one of the following components: (i) a gravimeter, or (ii) a scale including a nano-scale, or (iii) an xy and/or rotary actuator for a translational or rotational micro-positioning element, or (iv) an energy harvester, or (v) a relay that is configured to be monostable or bistable.

36. A micromechanical speaker, comprising:
a micromechanical structure with a movable bending unit, which includes a plurality of bending elements, wherein the plurality of bending elements are deflectable spring elements;
wherein at least one first spring element of the deflectable spring elements has a linear spring constant in an associated force-displacement diagram, and/or at least one second spring element of the deflectable spring elements has a non-linear spring constant in an associated force-displacement diagram,
wherein the first spring element and/or the second spring element can be functionally actuated,
wherein the first spring element and/or the second spring element are mechanically coupled, such that their common spring characteristic curve has an inflection point in the force-displacement diagram,
wherein the first spring element and/or the second spring element are laterally and/or rotationally pre-deflected by at least one actuating element in order to set the common spring characteristic curve for functional operation of the micromechanical structure,
wherein the at least one actuating element effects a temporary or permanent pre-deflection,
wherein the first spring element and/or the second spring element are functionally actuable for generating sound; and
a signal processing unit configured to apply and process signals from the micromechanical structure.
